(19) United States
(12) Patent Application Publication
(10) Pub. No.: US 2025/0147407 A1
(43) Pub. Date: May 8, 2025

(54) REFLECTION-TYPE MASK BLANK, METHOD FOR PRODUCING REFLECTION-TYPE MASK BLANK, REFLECTION-TYPE MASK, AND METHOD FOR PRODUCING REFLECTION-TYPE MASK

(71) Applicant: AGC Inc., Tokyo (JP)

(72) Inventors: Hiroaki ITO, Tokyo (JP); Daijiro Akagi, Tokyo (JP); Taiga Fudetani, Tokyo (JP)

(73) Assignee: AGC Inc., Tokyo (JP)

(21) Appl. No.: 19/013,708

(22) Filed: Jan. 8, 2025

Related U.S. Application Data
(63) Continuation of application No. PCT/JP2023/021774, filed on Jun. 12, 2023.

(30) Foreign Application Priority Data
Jul. 14, 2022 (JP) 2022-113391

(51) Int. Cl. G03F 1/24; G03F 1/40; G03F 1/48; G03F 1/58

(52) U.S. Cl. CPC G03F 1/24; G03F 1/40; G03F 1/48; G03F 1/58

(57) ABSTRACT

Provided is a reflective mask blank that is small in processing error in charged particle beam processing. A reflective mask blank (10a) includes a substrate (11), a multilayer reflective film (12) for reflecting EUV light, a protective film (13) and an absorber film (14) having a single-layer structure or a multilayer structure, wherein: any layer between the protective film (13) and the outermost layer located on the outermost side of the reflective mask blank (10a) opposite from the substrate (11) is an insulating layer having a sheet resistance of 1.0×10³ Ω/sq. or higher; and an internal electrical resistance between a surface of the outermost layer opposite from the substrate (11) and the protective film (13) is 100 kΩ or lower.

This application is a continuation of PCT Application No. PCT/JP2023/021774, filed on Jun. 12, 2023, which is based upon and claims the benefit of priority from Japanese Patent Application No. 2022-113391 filed on Jul. 14, 2022. The contents of those applications are incorporated herein by reference in their entireties.

### TECHNICAL FIELD

The present invention relates to a reflective mask used for EUV (Extreme Ultraviolet) exposure in an exposure process of semiconductor manufacturing, its production method, a reflective mask blank as an original plate of a reflective mask, and its production method.

### BACKGROUND ART

In recent years, EUV lithography using EUV light having a center wavelength of about 13.5 nm as a light source has been studied for further miniaturization of semiconductor devices.

For EUV exposure in EUV lithography, a reflective optical system and a reflective mask are used in view of the properties of EUV light. The reflective mask has a multilayer reflective film formed on a substrate to reflect EUV light and a patterned absorber film formed on the multilayer reflective film to absorb EUV light. As long as the EUV light reflectance is lowered by the absorber film, the absorber film can be formed of a material having a high EUV light absorptivity or can be a phase shift film. Herein, the phase shift film refers to a film that causes a phase shift in EUV light passing therethrough and lowers the EUV light reflectance by interference of the phase-shifted EUV lights.

In order to protect the multilayer reflective film during patterning of the absorber film, a protective film is often provided between the multilayer reflective film and the absorber film.

A reflective mask is obtained by, for example, providing a reflective mask blank in which a substrate, a multilayer reflective film for reflecting EUV light, a protective film and an adsorber film are arranged in this order and patterning the absorber film of the reflective mask blank. In EUV exposure using such a reflective mask, EUV light incident to the reflective mask from an illumination optical system of exposure equipment is reflected at a region where no absorber film is present (opening region) and is reduced in reflection at a region where the absorber film is present (non-opening region). As a result, the mask pattern is transferred as a resist pattern onto a wafer through a reduction projection optical system of exposure equipment. Then, post-processing is performed.

As the above-mentioned reflective mask blank to be subjected to patterning, Patent Document 1 discloses an embodiment of a reflective mask blank having, on a substrate, a multilayer reflective film, a protective film, a multilayer phase shift film and an etching mask film.

### PRIOR ART DOCUMENTS

### Patent Documents

Patent Document 1: Japanese Patent No. 6929983

### DISCLOSURE OF INVENTION

### Technical Problem

In the reflective mask blank or the reflective mask, an alignment mask for positioning may be formed by processing the absorber film and the film located on the side of the absorber film opposite from the protective film. In the formation of the alignment mark, the processing of the absorber film and the film located on the side of the absorber film opposite from the protective film may be performed by irradiation with a charged particle beam such as an electron beam, an ion beam or the like.

Further, the absorber film may be processed with a charged particle beam for the purpose of mask pattern repairment of the reflective mask.

To meet the trend for further miniaturization of semiconductor devices, there has been a demand for reflective mask blanks smaller in processing error in charged particle beam processing.

When the present inventors attempted to process the reflective mask blank of Patent Document 1 with a charged particle beam, charging of the reflective mask blank occurred due to the insulating properties of the outermost layer (in the embodiment of Patent Document 1, the etching mask layer) whereby the reflective mask blank was large in processing error and thus was in need of improvement.

The present invention has been made in view of the above-mentioned problem. It is an object of the present invention to provide a reflective mask blank small in processing error in charged particle beam processing.

It is also an object of the present invention provide a method for producing a reflective mask blank.

Further, it is an object of the present invention to provide a reflective mask and a method for producing a reflective mask.

### Solution to Problem

As a result of intensive studies made on the above-mentioned problem, the present inventors have found that it is possible to suppress charging of the reflective mask blank when the internal electrical resistance between the outermost layer located on the outermost side of the reflective mask blank opposite from the substrate and the protective film is lower than or equal to a predetermined value.

In other words, the present inventors have found that the above-mentioned problem can be solved by the following configurations.

[1]A reflective mask blank, comprising in the following order:
a substrate;
a multilayer reflective film for reflecting EUV light;
a protective film; and
an absorber film having a single-layer structure or a multilayer structure, wherein:
any layer between the outermost layer located on the outermost side of the reflective mask blank opposite from the substrate and the protective film is an insulating layer having a sheet resistance of 1.0×10³ Ω/sq. or higher; and
an internal electrical resistance between a surface of the outermost layer opposite from the substrate and the protective film is 100 kΩ or lower.

[2] The reflective mask blank according to [1], comprising a conductive layer arranged on the absorber film and having a sheet resistance of lower than 1.0×10³ Ω/sq., wherein the conductive layer is the outermost layer.

[3] The reflective mask blank according to [2], wherein the absorber film comprises the any layer formed as the insulating layer.

[4] The reflective mask blank according to [1], wherein:
the absorber film has a multilayer structure,
a top layer of the absorber film located farthest away from the substrate has a sheet resistance of lower than 1.0×10³ Ω/sq., and the top layer is the outermost layer.

[5] The reflective mask blank according to [4], wherein the absorber film comprises the any layer formed as the insulating layer.

[6] The reflective mask blank according to any one of [1] to [5], wherein the protective film has a sheet resistance of lower than 1.0×10³ Ω/sq.

[7] The reflective mask blank according to any one of [1] to [6], wherein the insulating layer has a thickness of 30 nm or smaller.

[8] The reflective mask blank according to any one of [1] to [7], comprising a conductor portion arranged between the outermost layer and the protective film to provide electrical conduction between layers respectively adjacent to both surfaces of the insulating layer.

[9] The reflective mask blank according to [8], wherein:
the conductor portion comprises a side conductor portion arranged on at least a side face of the insulating layer; and the side conductor portion is in contact with at least the layers respectively adjacent to the both surfaces of the insulating layer.

[10] The reflective mask blank according to [9], wherein the side conductor portion is arranged on side faces of all of the layers between the outermost layer and the protective film.

[11] The reflective mask blank according to [8], wherein the conductor portion comprises a through conductor portion arranged in and passing through the insulating layer in a thickness direction thereof.

[12] The reflective mask blank according to any one of [8] to [11], wherein the conductor portion contains at least one element selected from the group consisting of lithium, boron, carbon, fluorine, sodium, magnesium, aluminum, silicon, potassium, calcium, tin and transition metal elements.

[13] The reflective mask blank according to any one of [1] to [12], wherein the outermost layer contains at least one element selected from the group consisting of titanium, chromium, cobalt, nickel, copper, zirconium, niobium, molybdenum, ruthenium, rhodium, palladium, indium, tin, hafnium, tantalum, tungsten, rhenium, osmium, iridium and platinum.

[14] The reflective mask blank according to any one of [1] to [13], wherein the outermost layer contains at least one element selected from the group consisting of nitrogen, oxygen, boron, silicon and carbon.

[15]A reflective mask comprising an absorber film pattern formed by patterning the absorber film of the reflective mask blank according to any one of [1] to [14].

[16]A method for producing a reflective mask, comprising patterning the absorber film of the reflective mask blank according to any one of [1] to [14].

[17]A method for producing a reflective mask blank, comprising: providing a laminate which comprises, in the following order, a substrate, a multilayer reflective film for reflecting EUV light, a protective film and an absorber film having a single-layer structure or a multilayer structure and in which an insulating layer having a sheet resistance of 1.0×10³ Ω/sq. or higher is arranged on a side closer to the absorber film than the protective film; forming, on the absorber film, a conductive layer having a sheet resistance of lower than 1.0×10³ Ω/sq.; and forming a side conductor portion to cover at least a side face of the insulating layer and be in electrical conduction with the conductive layer.

[18]A method for producing a reflective mask blank, comprising: providing a laminate which comprises, in the following order, a substrate, a multilayer reflective film for reflecting EUV light, a conductive film and an absorber film having a single-layer structure or a multilayer structure and in which an insulating layer having a sheet resistance of 1.0×10³ Ω/sq. or higher is arranged on a side closer to the absorber film than the protective film, wherein the providing includes forming, on the absorber film, a top layer having a sheet resistance of lower than 1.0×10³ Ω/sq. as a part of the absorber film; and forming a side conductor portion to cover at least a side face of the insulating layer and be in electrical conduction with the top layer.

### Advantageous Effects of Invention

According to the present invention, there is provided a reflective mask blank small in processing error in charged particle beam processing.

According to the present invention, there is also provided a method for producing a reflective mask blank.

According to the present invention, there are further provided a reflective mask and a method for producing a reflective mask.

### BRIEF DESCRIPTION OF DRAWINGS

FIG. 1 is a schematic view illustrating an example of a reflective mask blank according to the present invention.

FIG. 2 is a schematic view illustrating an example of a reflective mask blank according to the present invention.

FIG. 3 is a schematic view illustrating an example of a reflective mask blank according to the present invention.

FIG. 4 is a schematic view illustrating an example of a reflective mask blank according to the present invention.

FIGS. 5A-5D is a schematic view illustrating an example of a process for producing a reflective mask using a reflective mask blank according to the present invention.

FIG. 6 is a schematic view for explaining a processing error in Examples.

### DESCRIPTION OF EMBODIMENTS

Hereinafter, the present invention will be described in detail below.

Although the following description of the features of the present invention may be made based on typical embodiments of the present invention, the present invention is not limited to these embodiments.

The meaning of each description in the present specification is as follows.

In the present specification, a numerical range expressed using “to” means a range including numerical values described before and after “to” as lower and upper limits.

In the present specification, each element may be represented by its corresponding chemical symbol.

### <Reflective Mask Blank>

A reflective mask blank according to the preset invention includes a substrate, a multilayer reflective film for reflecting EUV light, a protective film and an absorber film in this order, wherein: any layer between the outermost layer located on the outermost side of the reflective mask blank opposite from the substrate and the protective film is an insulating layer having a sheet resistance of 1.0×10³ Ω/sq. or higher; and an internal electrical resistance between a surface of the outermost layer opposite from the substrate and the protective film is 100 kΩ or lower.

The mechanism by which the reflective mask blank according to the present invention is small in processing error in charged particle beam processing is not always clear, but is assumed as follows by the present inventors.

In processing of the reflective mask blank (in particular, patterning of the absorber film), a charged particle beam is often used.

On the other hand, in the reflective mask blank, an insulating layer of 1.0×10³ Ω/sq. or higher may be arranged, as a layer difficult to etch by e.g. plasma etching, between the outermost layer and the protective film.

In the case where the reflective mask blank has the above-mentioned insulating layer, it is likely that, during continuous processing with a charged particle beam, the outermost layer will be charged to the same sign as the electric charge of charged particles of the charged particle beam. When the outermost layer is charged to the same sign as the electric charge of the charged particles, the charged particle beam is bent due to generation of a reaction force between the charged particles and the outermost layer whereby a processing error is easy to occur. The above-mentioned problem is more serious when the insulating layer is arranged on the outermost side of the reflective mask blank.

In the reflective mask blank according to the present invention, even though the insulating layer is arranged between the outermost layer and the protective film, the internal electrical resistance between the outermost layer and the protective film is 100 kΩ or lower. In other words, the reflective mask blank enables easy transfer of electric charge between the outermost layer and the protective film so that the outermost layer is not easily charged. It is assumed that, as a result of the above effect, the reflective mask blank according to the present invention is small in processing error.

Hereinafter, first to fourth embodiments of the reflective mask blank according to the present invention will be described below with reference to the drawings.

### <First Embodiment of Reflective Mask Blank>

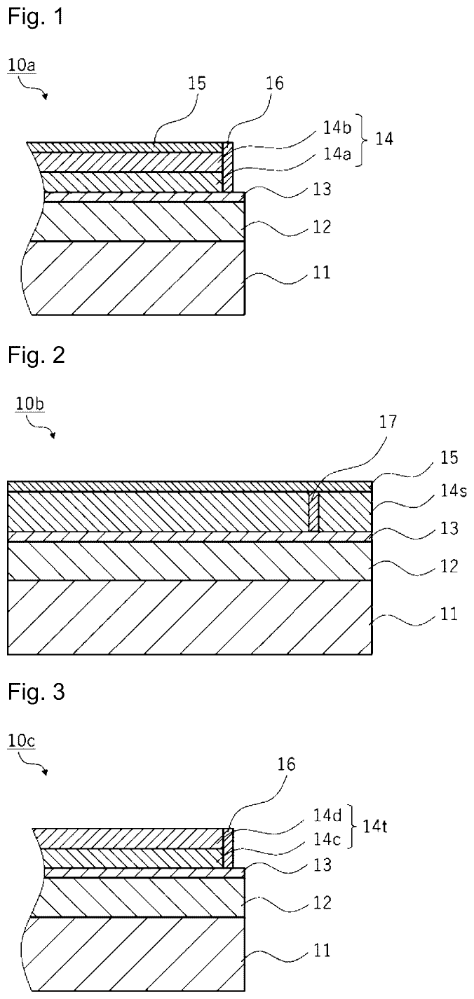

The first embodiment of the reflective mask blank according to the present invention is shown in FIG. 1.

A reflective mask blank 10a shown in FIG. 1 has a substrate 11, a multilayer reflective film 12, a protective film 13, an absorber film 14 and a conductive layer 15 arranged in this order. Further, a conductor portion 16 is arranged on side faces of the absorber film 14 and the conductive layer 15. The side conductor portion 16 is in contact with the side face of the conductive layer 15 and a surface of the protective film 13. The absorber film 14 includes a first absorber film 14a and a second absorber film 14b arranged in this order from the substrate 11 side. The second absorber film 14b corresponds to the insulating layer having a sheet resistance of 1.0×10³ Ω/sq. or higher. Furthermore, the conductive layer 15 corresponds to the outermost layer located on the outermost side of the reflective mask blank 10a opposite from the substrate 11.

In the reflective mask blank 10a of FIG. 1, the second absorber film 14b as the insulating layer is arranged between the conductive layer 15 as the outermost layer and the protective film 13. In the reflective mask blank 10a, on the other hand, the side conductor portion 16 is arranged in contact with the side face of the conductive layer 15 and the surface of the protective film 13 so that the side conductor portion 16 ensures conductivity between the conductive layer 15 and the protective film 13. Thus, the reflective mask blank 10a achieves an internal electrical resistance of 100 kΩ or lower between the surface of the conductive layer 15 as the outermost layer opposite from the substrate 11 and the protective film 13 even though the second absorber film 14b as the insulating layer is arranged between the conductive layer 15 as the outermost layer and the protective film 13. The achievement of such an internal electrical resistance allows, even when charged particle beam processing is performed from the surface of the conductive layer 15, electric charge in the conductive layer 15 as the outermost layer to be easily transferred to the protective film 13, thereby suppressing charging of the conductive layer 15 and consequently making it less likely that a processing error will occur due to bending of the charged particle beam.

The internal electrical resistance can be measured by the following method. First, a region of the protective film of the reflective mask blank is exposed by etching or the other method. Then, an electrical resistance between the exposed protective film and the surface of the outermost layer of the reflective mask blank opposite from the substrate is measured with a Manual Prober (model number: HMP-400, manufactured by HiSOL Inc.). In this measurement, the straight-line distance between the measurement terminal in contact with the protective film and the measurement terminal in contact with the outermost layer in a plane direction of the substrate is set to 20 mm.

By the above-mentioned method, when the electrical resistance of the protective film is low, the internal electrical resistance between the surface of the outermost layer opposite from the substrate and the protective film can be measured.

When the electrical resistance of the protective film is low, the internal electrical resistance mainly depends on the electrical resistance of a layer located on the side of the protective film opposite from the substrate in the vertical direction of the substrate and the thickness of such a layer; and the electrical resistance in the horizontal direction of the substrate can be ignored. Therefore, the internal electrical resistance, even when measured by changing the above-mentioned straight-line distance from 20 mm to 100 mm, becomes equivalent to that in the case of 20 mm.

The internal electrical resistance is preferably 50 kΩ or lower, more preferably 20 kΩ or lower, still more preferably 10 kΩ or lower, particularly preferably 1 kΩ or lower, most preferably 250Ω or lower. The lower limit of the internal electrical resistance is not particularly limited. The internal electrical resistance is, for example, 0.01Ω or higher, and is often 50Ω or higher.

The configurations of the first embodiment of the reflective mask blank according to the present invention will be now described in more detail below.

### [Substrate]

The substrate in the first embodiment of the reflective mask blank according to the present invention is preferably low in thermal expansion coefficient. When the thermal expansion coefficient of the substrate is low, it is possible to suppress a distortion in absorber film pattern due to heat generated during EUV exposure.

The thermal expansion coefficient of the substrate at 20° C. is preferably 0±1.0×10⁻⁷/° C., more preferably 0±0.3×10⁻⁷/° C.

As the material having a low thermal expansion coefficient, SiO₂—TiO₂ glass may be mentioned. The material of the substrate is however not limited to this glass. Substrates of crystallized glass in which a β-quartz solid solution is precipitated, quartz glass, metallic silicon, metal and the like are also usable.

The SiO₂—TiO₂ glass is preferably quartz glass having a SiO₂ content of 90 to 95 mass % and a TiO₂ content of 5 to 10 mass %. When the TiO₂ content is 5 to 10 mass %, the linear expansion coefficient of the glass at around room temperature is substantially zero so that almost no dimensional change occurs at around room temperature. The SiO₂—TiO₂ glass may contain any trace component other than SiO₂ and TiO₂.

A surface of the substrate on which the multilayer reflective film is stacked (hereinafter also referred to as a “first main surface”) is preferably high in surface smoothness. The surface smoothness of the first main surface can be evaluated by surface roughness. The surface roughness of the first main surface is preferably 0.15 nm or less in terms of the root mean square roughness Rq. Herein, the surface roughness can be measured with an atomic force microscope. The surface roughness will be hereinafter explained as the root mean square roughness Rq based on JIS B0601.

In order to increase the pattern transfer accuracy and positional accuracy of a reflective mask obtained from the reflective mask blank, the first main surface is preferably surface-processed to a predetermined level of flatness. The flatness of the substrate at a predetermined region (for example, a region of 132 mm×132 mm) of the first main surface is preferably 100 nm or less, more preferably 50 nm or less, still more preferably 30 nm or less. The flatness can be measured with a flatness measurement system manufactured by FUJINON Corporation.

The size, thickness etc. of the substrate are determined as appropriate depending on the design value of the mask and the like. For example, the substrate may have an outer size of 6 inches (152 mm) square and a thickness of 0.25 inches (6.3 mm). Further, the substrate is preferably high in rigidity in order to prevent deformation due to film stress of the film (multilayer reflective film, phase shift film or the like) formed on the substrate. For example, the Young's modulus of the substrate is preferably 65 GPa or higher.

### [Multilayer Reflective Film]

The multilayer reflective film in the first embodiment of the reflective mask blank according to the present invention is not particularly limited as long as it has properties desired for reflective films of EUV mask blanks. The multilayer reflective film is preferably high in EUV light reflectance. More specifically, when a surface of the multilayer reflective film is irradiated with EUV light at an incident angle of 6°, the maximum value of the EUV light reflectance in the vicinity of a wavelength of 13.5 nm is preferably 60% or higher, more preferably 65% or higher. Even in the case where the protective film is stacked on the multilayer reflective film, the maximum value of the EUV light reflectance in the vicinity of a wavelength of 13.5 nm is also preferably 60% or higher, more preferably 65% or higher.

As the multilayer reflective film, generally used is a multilayer reflective film in which a high refractive index layer having a high refractive index to EUV light and a low refractive index layer having a low refractive index to EUV light are alternately stacked plural times in order to achieve a high EUV light reflectance.

Assuming a stacked unit in which a high refractive index layer and a low refractive index layer are stacked in this order from the substrate side as one cycle, the multilayer reflective film may have a laminated structure formed by a plurality of cycles. Assuming a stacked unit in which a low refractive index layer and a high refractive index layer are stacked in this order from the substate side, the multilayer reflective film may have a laminated structure formed by a plurality of cycles.

As the high refractive index layer, a layer containing Si can be used. The material containing Si can be elemental Si or a Si compound containing Si and one or more selected from the group consisting of B, C, N and O. With the use of such Si-containing high refractive index layers, there can be obtained a reflective mask high in EUV light reflectance.

As the low refractive index layer, a layer containing a metal selected from the group consisting of Mo, Ru, Rh and Pt or an alloy thereof can be used.

In the high refractive index layer, Si is widely used. In the low refractive index layer, Mo is widely used. In other words, the most commonly used is a Mo/Si multilayer reflective film. The multilayer reflective film is however not limited to this type. A Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film and a Si/Ru/Mo/Ru multilayer reflective film are also usable.

The thickness of each of the layers and the number of repeating units of the layers in the multilayer reflective film are selected as appropriate depending on the film materials used and the EUV light reflectance required for the reflective film. For example, to form a Mo/Si multilayer reflective film with a maximum EUV light reflectance of 60% or higher, Mo layers of 2.3±0.1 nm thickness and Si layers of 4.5±0.1 nm thickness can be alternately stacked such that the number of repeating units of these layers ranges from 30 to 60.

Each of the layers constituting the multilayer reflective film can be formed with a desired thickness by a known film formation method such as a magnetron sputtering method, an ion beam sputtering method or the like. For example, when the multilayer reflective film is formed by ion beam sputtering, the sputtering is performed with the supply of ion particles from an ion source to a target of the high refractive index material and to a target of the low refractive index material. In the case where the multilayer reflective film is a Mo/Si multilayer reflective film, a Si layer of predetermined thickness is first formed on the substrate using a Si target; and a Mo layer of predetermined thickness is then formed using a Mo target. Assuming such stacking of Si and Mo layers as one cycle, the Mo/Si multilayer reflective film is formed by 30 to 60 cycles of stacking.

The layer of the multilayer reflective film in contact with the protective film is preferably a layer of hardly oxidizable material. The layer of hardly oxidizable material functions as a capping layer for the multilayer reflective film. As the layer of hardly oxidizable material, a Si layer may be mentioned. In the case where: the multilayer reflective film is a Si/Mo multilayer reflective film; and a Si layer is formed as the layer in contact with the protective film, the layer in contact with the protective layer functions as a capping layer for the multilayer reflective film. In this case, the thickness of the capping layer is preferably 11±2 nm.

### [Protective Film]

In the first embodiment of the reflective mask blank according to the present invention, the protective film is provided for the purpose of protecting the multilayer reflective film such that, during patterning of the absorber film by an etching process (in general, a dry etching process), the multilayer reflective film will not be damaged by the etching process.

As the material capable of achieving the above-mentioned purpose, a material containing at least one element selected from the group consisting of Ru and Rh may be mentioned. In other words, the protective film preferably contains at least one element selected from the group consisting of Ru and Rh.

Specific examples of the above material include: an elemental Ru metal; a Ru alloy containing Ru and one or more metals selected from the group consisting of Si, Ti, Nb, Rh and Zr; an elemental Rh metal; a Rh alloy containing Rh and one or more metals selected from the group consisting of Si, Ti, Nb, Ra, Ta and Zr; and Rh-based materials such as a Rh-containing nitride containing the above-mentioned Rh alloy and nitrogen, a Rh-containing oxynitride containing the above-mentioned Rh alloy, nitrogen and oxygen, and the like.

As the material capable of achieving the above-mentioned purpose, Al, a nitride containing this metal and nitrogen, Al₂O₃, and the like may be also mentioned. Among the others, an elemental Ru metal, a Ru alloy, an elemental Rh metal or a Rh alloy is preferred as the material capable of achieving the above-mentioned purpose. A Ru—Si alloy is preferred as the Ru alloy. A Rh—Si alloy is preferred as the Rh alloy.

The film thickness of the protective film is not particularly limited as long as the protective film performs its function. In order to maintain the reflectance of EUV light reflected by the multilayer reflective film, the film thickness of the protective film is preferably 1 to 10 nm, more preferably 1.5 to 6 nm, still more preferably 2 to 5 nm. It is preferable that the material of the protective film is an elemental Ru metal, a Ru alloy, an elemental Rh metal or a Rh alloy and, at the same time, the film thickness of the protective film is in the above-specified preferable range.

The protective film may be a single-layer film or a multilayer film constituted by a plurality of layers. In the case where the protective film is a multilayer film, each of the layers constituting the multilayer film is preferably formed of the preferred material mentioned above. Further, in the case where the protective film is a multilayer film, the total film thickness of the multilayer film is preferably in the above-specified preferable protective film thickness range.

In order to allow a smaller processing error in charged particle beam processing, the sheet resistance of the protective film is preferably lower than 1.0×10³ Ω/sq., more preferably 7.5×10² Ω/sq. or lower, still more preferably 5.0×10² Ω/sq. or lower. The lower limit of the sheet resistance of the protective film is not particularly limited. The sheet resistance of the protective film is, for example, 1.0×10⁻¹ Ω/sq. or higher, and is preferably 1.0×10⁰ Ω/sq. or higher.

The sheet resistance can be measured according to a four-point probe method by contact of measurement terminals with the protective film. More specifically, the sheet resistance can be measured with a surface resistivity meter (Loresta GX MCP-T700, manufactured by Nittoseiko Analytech Co., Ltd.).

The sheet resistance of the protective film may be measured by, for example, exposing the protective film of the reflective mask blank by etching or the other method. Further, the sheet resistance of the protective film may be measured by analyzing the components and thickness of the protective film by a known analysis method (such as e.g. transmission scanning electron microscopy-energy dispersive X-ray spectroscopy) and preparing a measurement sample with the same components and thickness on another substrate (e.g. an insulating substrate), or may be measured by preparing a measurement sample on another substrate (e.g. an insulating substrate) under the same conditions as the formation conditions of the protective film.

The sheet resistance of the protective film may be measured using a laminate obtained in the process of manufacturing the reflective mask blank, that is, a sample in which the substate, the multilayer reflective film and the protective film are stacked.

By the above-mentioned methods, similar sheet resistance values can be obtained.

The protective film can be formed by a known film formation method such as a magnetron sputtering method, an ion beam sputtering method or the like. In the case where a Ru film is formed by magnetron sputtering, the sputtering is preferably performed using a Ru target as the target and Ar gas as the sputtering gas.

### [Absorber Film]

The absorber film (the first absorber film and the second absorber film) in the first embodiment of the reflective mask blank according to the present invention is required to, when the absorber film is patterned, generate a high contrast between EUV light reflected by the multilayer reflective film and EUV light reflected by the absorber film. The patterned absorber film (absorber film pattern) may perform the function of a binary mask to absorb EUV light, or may perform the function of a phase shift mask to reflect EUV light and generate a contrast by interference of the reflected light with EUV light from the multilayer reflective film.

Further, the absorber film may be a film having a so-called anti-reflective function. In other words, in the case where the absorber film is a multilayer film (an absorber film having a multilayer structure), a layer of the absorber film located opposite from the protective film may be an anti-reflective film for inspection of the absorber film pattern by irradiation with inspection light (e.g. light having a wavelength of 193 to 248 nm). The material constituting the absorber film is preferably, for example, a material containing at least one element (first element) selected from the group consisting of Cr, Co, Ni, Cu, Nb, Mo, Au, Ag, Ru, Rh, Pd, In, Sn, Hf, Ta, W, Re, Os, Ir and Pt.

In the case where the absorber film pattern is used as a binary mask, the absorber film needs to have a low EUV light reflectance by absorption of EUV light. More specifically, when a surface of the absorber film is irradiated with EUV light, the maximum value of the EUV light reflectance in the vicinity of a wavelength of 13.5 nm is preferably 2% or lower.

The absorber film (the first absorber film and the second absorber film) preferably contains one or more elements selected from the group consisting of Ta, Ti, Sn and Cr and one or more elements selected from the group consisting of O, N, B, Hf and H. Among others, preferably contained is N or B. By containing N or B, the crystalline state of the absorber film can be made amorphous or microcrystalline.

In the case where the absorber film pattern is used as a binary mask, the film thickness of the absorber film is preferably 40 to 70 nm, more preferably 50 to 65 nm.

In the case where the absorber film pattern is used as a phase shift mask, the EUV light reflectance of the absorber film is preferably 2% or higher. In order to obtain a sufficient phase shift effect, the EUV light reflectance of the absorber film is more preferably 9 to 15%. With the use of the absorber film as a phase shift mask, the contrast of an optical image on a wafer is improved; and the exposure margin is increased.

As the material constituting the phase shift mask, for example, a material containing one or more elements selected from the group consisting of Cr, Nb, Ru, Ta, Re, Ir, Ag, Os, Au, Pd and Pt may be mentioned.

Preferably, the absorber film includes a first layer containing a first element selected from the group consisting of Ru, Re, Ir, Ag, Os, Au, Pd and Pt and a second layer containing a second element selected from the group consisting of Nb, Ta and Cr. The first layer and the second layer may preferably further contain at least one element selected from the group consisting of N, O, B, Si and C. It is also preferable that: the first layer corresponds to the first absorber film; and the second layer corresponds to the second absorber film.

Examples of the material constituting the phase shift mask include an elemental substance of the above-mentioned element, an alloy containing the above-mentioned element, an oxide of the above-mentioned element, a nitride of the above-mentioned element, an oxynitride of the above-mentioned element, a boride of the above-mentioned element, a silicide of the above-mentioned element, a carbide of the above-mentioned element, a composite oxide containing one or more of the above-mentioned elements, a composite nitride containing one or more of the above-mentioned elements, a composite oxynitride containing one or more of the above-mentioned elements, a composite boride containing one or more of the above-mentioned elements, a composite silicide containing one or more of the above-mentioned elements, and a composite carbide containing one or more of the above-mentioned elements.

For example, as the material constituting the phase shift mask, there may be mentioned an elemental Ru metal, a Ru nitride, a Ru oxynitride, a Ta nitride, a Ta oxynitride, a Ru alloy containing Ru and one or more metals selected from the group consisting of Cr, Au, Pt, Re, Hf, Ti and Si, an alloy of Ta and Nb, an oxide containing a Ru alloy or TaNb alloy and oxygen, a nitride containing a Ru alloy or TaNb alloy and nitrogen, an oxynitride containing a Ru alloy or TaNb alloy, oxygen and nitrogen, and the like.

However, as the material constituting the layer of the phase shift mask in contact with the protective film, a material different from the material of the protective film is selected.

In the case where the absorber film pattern is used as a phase shift mask, the film thickness of the absorber film is preferably 30 to 60 nm, more preferably 35 to 55 nm.

The crystalline state of the absorber film is preferably amorphous. This leads to improved smoothness and flatness of the absorber film. When the smoothness and flatness of the absorber film is improved, the absorber film pattern becomes small in edge roughness and thus can be improved in dimensional accuracy.

The absorber film can be formed by a known film formation method such as a magnetron sputtering method, an ion beam sputtering method or the like. For example, in the case where an Ru oxide film is formed as the absorber film by magnetron sputtering, the absorber film can be formed by sputtering using a Ru target with the supply of a gas containing Ar gas and oxygen gas.

In FIG. 1, the absorber film 14 has a two-layer structure of the first absorber film 14a and the second absorber film 14b.

As mentioned above, the second absorber film 14b is the layer having a sheet resistance of 1.0×10³ Ω/sq. or higher. In other hand, the second absorber film 14b not only functions as the absorber film but also corresponds to the insulating layer having a sheet resistance higher than or equal to a predetermined value.

The above sheet resistance can be measured in the same manner as the measurement method of the sheet resistance of the protective film.

As the material constituting the second absorber film 14b, for example, a material containing the above-mentioned second element and an element selected from the group consisting of O and B may be mentioned. Specific examples of such a material include a Ta oxide, a Ta oxynitride, a Ta boride, a Ta oxyboride, a Cr oxide, a Cr oxynitride and a Cr oxyboride.

The thickness of the second absorber film 14b is preferably 50 nm or smaller, more preferably 30 nm or smaller. The lower limit of the thickness of the second absorber layer is not particularly limited. The thickness of the second absorber layer is, for example, 1 nm or larger, and is often 5 nm or larger.

In order to allow a smaller processing error in charged particle beam processing, the sheet resistance of the first absorber film 14a is preferably lower than 1.0×10³ Ω/sq., more preferably 7.5×10² Ω/sq. or lower, still more preferably 5.0×10² Ω/sq. or lower. The lower limit of the sheet resistance of the first absorber film 14 is not particularly limited. The sheet resistance of the first absorber film 14a is for example 1.0×10⁻¹ Ω/sq. or higher, and is preferably 1.0×10⁰ Ω/sq. or higher.

The above sheet resistance can be measured in the same manner as the measurement method of the sheet resistance of the protective film.

As the material constituting the first absorber film 14a, for example, a material containing the above-mentioned first element may be mentioned. Specific examples of such a material include an elemental Ru metal, a Ru nitride, a Ru oxide, a Ru oxynitride, a Ru boride, an elemental Ir metal, an Ir nitride, an Ir oxide, an Ir oxynitride, an Ir boride, a Ta nitride and an elemental Pt metal.

### [Conductive Layer]

The conductive layer in the first embodiment of the reflective mask blank according to the present invention corresponds to the outermost layer located on the outermost side of the reflective mask blank opposite from the substrate.

The sheet resistance of the conductive layer is preferably lower than 1.0×10³ Ω/sq., more preferably 7.5×10² Ω/sq. or lower, still more preferably 5.0×10² Ω/sq. or lower. The lower limit of the sheet resistance of the conductive layer is not particularly limited. The sheet resistance of the conductive layer is, for example, 1.0×10⁻¹ Ω/sq. or higher, and is preferably 1.0×10⁰ Ω/sq. or higher.

The sheet resistance can be measured in accordance with the measurement method of the sheet resistance of the protective film.

As the material constituting the conductive layer as the outermost layer, at least one element (first metal element) selected from the group consisting of Ti, Cr, Co, Ni, Cu, Zr, Nb, Mo, Ru, Rh, Pd, In, Sn, Hf, Ta, W, Re, Os, Ir and Pt may be mentioned.

Further, the conductive layer as the outermost layer may preferably contains at least one element (first non-metal element) selected from the group consisting of N, O, B, Si and C.

The conductive layer as the outermost layer may contain the first metal element and the first non-metal element.

The conductive layer in the first embodiment of the reflective mask blank according to the present invention may be a hard mask film.

As an element contained in the material constituting the hard mask film, the above first metal element may be mentioned. As such an element, preferred is at least one element selected from the group consisting of Ti, Cr, Co, Ni, Cu, Zr, Nb, Mo, Ru, Rh, Pd, In, Sn, Hf, Ta and Ir.

As the hard mask film, preferably used is a film resistant to dry etching, such as a Si-based film, a Cr-based film, a Nb-based film, a Mo-based film, a Ru-based film, a Ta-based film or the like. The hard mask film is preferably a mask formed of a material containing the above-mentioned element and one or more elements selected from the group consisting of O, N, C, B and H, more preferably a film formed of a material containing the above-mentioned element and one or more elements selected from the group consisting of N and C. Hereinafter, a material containing Cr and O may be expressed as “CrO”; a material containing Cr, O and N may be expressed as “CrON”; and other materials may be expressed likewise.

Examples of the material constituting the Cr-base film include Cr (elemental Cr), CrC, CrB, CrBN, CrO, CrN, CrON and the like. Preferred is Cr or CrN.

Examples of the material constituting the Nb-based film include Nb (elemental Nb), NbC, NbB, NbBN, NbO, NbN, NbON and the like. Preferred is Nb or NbN.

Examples of the material constituting the Mo-based film include Mo (elemental Mo), MoC, MoB, MoBN, MoO, MoN, MoON and the like. Preferred is Mo or MoN.

Examples of the material constituting the Ru-based film are Ru (elemental Ru), RuC, RuB, RuBN, RuO, RuN, RuON and the like. Preferred is RuO, RuN or RuON.

Examples of the material constituting the Ta-based film include Ta (elemental Ta), TaC, TaB, TaBN, TaO, TaN, TaON and the like. Preferred is Ta or TaN.

With the formation of the hard mask film on the absorber film, dry etching can be performed even when the minimum line width of the absorber film pattern becomes small. It is thus effective for miniaturization of the absorber film pattern.

The film thickness of the hard mask film is preferably 1 to 20 nm, more preferably 5 to 15 nm.

The hard mask film can be formed by a known film formation method such as a magnetron sputtering method, an ion beam sputtering method or the like.

In the case where a RuON film is formed by a sputtering method, reactive sputtering may be performed using a Ru target in a mixed gas atmosphere of inert gas containing at least one of He, Ar, Ne, Kr and Xe, oxygen gas and nitrogen gas.

### [Insulating Layer]

The insulating layer in the first embodiment of the reflective mask blank according to the present invention is a layer having a sheet resistance of 1.0×10³ Ω/sq. or higher. In the embodiment shown in FIG. 1, the second absorber film 14b corresponds to the insulating layer.

The thickness of the insulating layer is preferably 50 nm or smaller, more preferably 30 nm or smaller. The lower limit of the thickness of the insulating layer is not particularly limited. The thickness of the insulating layer is, for example, 1 nm or larger, and is often 5 nm or larger.

The sheet resistance of the layer adjacent to the insulating layer is preferably lower than 1.0×10³ Ω/sq., more preferably 7.5×10² Ω/sq. or lower, still more preferably 5.0×10² Ω/sq. or lower. In the embodiment shown in FIG. 1, the sheet resistance of the conductive layer 15 and the first absorber film 14a is preferably in the above preferable range.

### [Side Conductor Portion]

In the first embodiment of the reflective mask blank according to the present invention, the side conductor portion is arranged on the side faces of the absorber film and the conductive layer. The side conductor portion is a member brought into contact with the side face of the conductive layer and the surface of the protective film to ensure electrical conduction between the conductive layer as the outermost layer and the protective film. More specifically, in FIG. 1, the side conductor portion 16 is in contact with the first absorber film 14a and the conductive layer 15, which are respectively adjacent to both surfaces of the second absorber film 14b, and in contact with the protective film 13.

The material constituting the side conductor portion preferably contains, for example, at least one element selected from the group consisting of Li, B, C, F, Na, Mg, Al, Si, K, Ca, Sn and transition metal elements.

Among others, the material constituting the side conductor portion is preferably the same as the material constituting the conductive layer in terms of productivity.

The method for forming the side conductor portion is not particularly limited. The side conductor portion can be obtained by, for example, forming the multilayer reflective layer, the protective film, the absorber film and the conductive layer on the substrate, and then, sputtering the material constituting the side conductor portion.

In the case where the side conductor portion is formed of the same material as the conductive layer, the side conductor portion may be formed simultaneously with the formation of the conductive layer.

More specifically, for example, the multilayer reflective film and the protective film are first formed in this order on the substrate. Next, the absorber film is formed by limiting the area of formation of the absorber film such that an end of the absorber film to be formed is positioned closer to the center of the substrate than an end of the protective film formed. After the formation of the absorber film, the conductive layer is formed on the absorber film, and simultaneously, the side conductor portion of the same material as the conductive layer is formed on the side face of the absorber film.

The detailed production procedure will be described later.

### [Bottom Conductive Film]

In the first embodiment of the reflective mask blank according to the present invention, a bottom conductive film may be arranged on a bottom surface (second main surface) of the substrate opposite to the first main surface. The formation of the bottom conductive film enables handling of the reflective mask blank by electrostatic chuck.

The bottom conductive film is preferably low in sheet resistance. The sheet resistance of the bottom conductive film is, for example, preferably 200 Ω/sq. or lower, more preferably 100 Ω/sq. or lower.

The material constituting the bottom conductive film can selected from a wide range of materials described in publicly known documents. For example, a high dielectric constant coating disclosed in JP-A-2003-501823, more specifically a coating of Si, Mo, Cr, CrON or TaSi is applicable. The material constituting the bottom conductive film may be a Cr compound containing Cr and one or more selected from the group consisting of B, N, O and C or a Ta compound containing Ta and one or more selected from the group consisting of B, N, O and C.

The thickness of the bottom conductive film is preferably 10 to 1000 nm, more preferably 10 to 400 nm.

Further, the bottom conductive film may have the function of adjusting stress on the second main surface side of the reflective mask blank. In other words, the bottom conductive film may have the function of adjusting the flatness of the reflective mask blank by balancing stress from the respective films formed on the first main surface side.

The bottom conductive film can be formed by a known film formation method such as a sputtering method e.g. a magnetron sputtering method or an ion sputtering method, a CVD method, a vacuum deposition method, or an electrolytic plating method.

In the first embodiment of the reflective mask blank according to the present invention as shown in FIG. 1, the absorber film has a two-layer structure. The present invention is however not limited to this embodiment.

In an alternative embodiment, the absorber film may have a structure of three or more layers, one of which corresponds to the above-mentioned insulating layer. For example, the absorber film may have a three-layer structure in which: the first absorber film, the second absorber film and the third absorber film are arranged in this order from the substrate side; and the third absorber film corresponds to the above-mentioned insulating layer.

Alternatively, the absorber film may have a single-layer structure in which the single layer itself corresponds to the above-mentioned insulating layer.

In the first embodiment of the reflective mask blank according to the present invention as shown in FIG. 1, one of the two layers of the absorber film corresponds to the above-mentioned insulating layer. The present invention is however not limited to this embodiment.

For example, all of the layers of the absorber film may correspond to the above-mentioned insulating layer.

In the reflective mask blank according to the present invention, any layer between the outermost layer and the protective film is the above-mentioned insulating layer. Differently from the embodiment shown in FIG. 1, the insulating layer may be formed as another member different from the absorber film.

In the first embodiment of the reflective mask blank according to the present invention as shown in FIG. 1, the side conductor portion is arranged on the side faces of the absorber film and the conductive layer. The present invention is however not limited to this embodiment as long as the internal electrical resistance is in the above-mentioned predetermined range.

For example, in the case where the sheet resistance of the first absorber film 14a is lower than 1.0×10³ Ω/sq. in FIG. 1, the side conductor portion can be arranged to cover at least the side face of the second absorber film 14b as the insulating layer and be in contact with the conductive layer 15 and the first absorber film 14a. In this case, the side conductor portion ensures conductivity between the conductive layer 15 and the first absorber film 14a, which are respectively adjacent to both surfaces of the second absorber film 14b as the insulating layer, thereby achieving the above-mentioned internal electrical resistance. In other words, the side conductor portion is preferably arranged, at least on the side face of the insulating layer, to be in contact with the layers respectively adjacent to both surfaces of the insulating layer and thereby ensure conductivity between these layers.

In the first embodiment of the reflective mask blank according to the present invention as shown in FIG. 1, the positions of the ends of the absorber film and the conductive layer are substantially in agreement with each other and are closer to the center of the substrate than the position of the end of the protective film. The present invention is however not limited to this embodiment.

For example, the positions of the ends of the protective film, the absorber film and the conductive layer may be substantially in agreement with one another; and the side conductor portion may be arranged on the side faces of the protective film, the absorber film and the conductive layer. Further, the positions of the ends of the substrate, the multilayer reflective film, the protective film, the absorber film and the conductive layer may be substantially in agreement with each other; and the side conductor portion may be arranged on the entire side face of the reflective mask blank.

### <Second Embodiment of Reflective Mask Blank>

The second embodiment of the reflective mask blank according to the present invention is shown in FIG. 2.

A reflective mask blank 10b shown in FIG. 2 has a substrate 11, a multilayer reflective film 12, a protective film 13, an absorber film 14s and a conductive layer 15 arranged in this order. Further, a though conductor portion 17 is arranged passing through the absorber film 14s in the thickness direction. The though conductor portion 17 is in contact with the conductive layer 15 and the protective film 13. The absorber film 14s corresponds to the insulating layer having a sheet resistance of 1.0×10³ Ω/sq. or higher. Furthermore, the conductive layer 15 corresponds to the outermost layer located on the outermost side of the reflective mask blank 10b opposite from the substrate 11.

In the reflective mask blank 10b of FIG. 2, the absorber film 14s as the insulating layer is arranged between the conductive layer 15 as the outermost layer and the protective film 13. In the reflective mask blank 10b, on the other hand, the through conductor portion 17 is arranged passing through the absorber film 14s in the thickness direction so that the through conductor portion 17 ensures conductivity between the conductive layer 15 and the protective film 13. Thus, the reflective mask blank 10b achieves an internal electrical resistance of 100 kΩ or lower between the surface of the conductive layer 15 as the outermost layer opposite from the substrate 11 and the protective film 13 even though the absorber film 14s as the insulating layer is arranged between the conductive layer 15 as the outermost layer and the protective film 13. The achievement of such an internal electrical resistance allows, even when charged particle beam processing is performed from the surface of the conductive layer 15, electric charge in the conductive layer 15 as the outermost layer to be easily transferred to the protective film 13, thereby suppressing charging of the conductive layer 15 and consequently making it less likely that a processing error will occur due to bending of the charged particle beam.

The measurement method of the internal electrical resistance between the outermost layer and the protective film in the second embodiment of the reflective mask blank according to the present invention is the same as the measurement method of the internal electrical resistance in the first embodiment of the reflective mask blank.

Further, the preferable range of the internal electrical resistance in the second embodiment of the reflective mask blank according to the present invention is the same as the preferable range of the internal electrical resistance in the first embodiment of the reflective mask blank.

When compared, the reflective mask blank 10a of FIG. 1 and the reflective mask blank 10b of FIG. 2 are the same in configurations except that the reflective mask blank 10b of FIG. 2 does not have a side conductor portion but has a through conductor portion. Thus, description of the same configurations will be omitted; and the following description will mainly be made only of the through conductor portion.

### [Through Conductor Portion]

In the second embodiment of the reflective mask blank according to the present invention, the through conductor portion is arranged in the absorber film as the insulating layer. The though conductor portion is a member brought into contact with a surface of the conductive layer and a surface of the protective layer to ensure electrical conduction between the conductive layer as the outermost layer and the protective film. More specifically, in FIG. 2, the through conductor portion 17 is in contact with the protective film 13 and the conductive layer 15, which are respectively adjacent to both surfaces of the absorber film 14s as the insulating layer.

The material constituting the through conductor portion preferably contains, for example, at least one element selected from the group consisting of Li, B, C, F, Na, Mg, Al, Si, K, Ca, Sn and transition metal elements.

Among others, the material constituting the through conductor portion is preferably the same as the material constituting the conductive layer in terms of productivity.

Although the through conductor portion 17 is arranged at one location in the embodiment shown in FIG. 2, such conductor portions may be arranged at two or more locations.

The shape of the through conductor portion is not particularly limited, and can be any of a cylindrical column shape, a polygonal prism shape, a conical shape, a polygonal pyramid shape, a circular truncated cone, a polygonal truncated pyramid shape, a spherical shape, a polyhedral shape and the like.

The maximum width of a cross section of the through conductor portion is preferably 1 nm to 100 μm, more preferably 10 nm to 15 μm.

In the embodiment shown in FIG. 2, the through conductor portion 17 is, when viewed in cross section, filled with the material constituting the through conductor portion. However, the through conductor portion is not necessarily entirely filled with the material constituting the through conductor portion as long as it ensures electrical conduction between the conductive layer and the protective film. In other words, the through conductor portion may have such a structure that the material constituting the through conductor portion exists in a part of the cross section of the through conductor portion, and may have a hollow region or a region in which another material exists.

The method for forming the through conductor portion is not particularly limited. For example, there may be mentioned a method in which a through hole is formed in the insulating layer (in FIG. 2, the absorber film) during or after the formation of the insulating layer, followed by forming the conductive layer. By the above-mentioned method, the through conductor portion is formed of the same material as the conductive layer.

As the method for forming the though conductor portion though the insulating layer in the thickness direction, there may also be mentioned a method in which, at the time of formation of the insulating layer, particles having a height larger than or equal to the thickness of the insulating layer to be formed are applied to the surface of the layer on which the insulating layer is to be formed. As the method for applying the particles, for example, there may be mentioned a method in which previously formed particles are arranged by a manipulator or the like to the surface of the layer on which the insulating layer is to be formed.

In the second embodiment of the reflective mask blank according to the present invention as shown in FIG. 2, the absorber film has a single-layer structure. The present invention is however not limited to this embodiment. The absorber film may be a multilayer film of two or more layers (a multilayer absorber film). In the case where: the absorber film is a multilayer film; and one of the layers constituting the absorber film corresponds to the insulating layer, the through conductor portion is arranged passing through any of the layers of the absorber film corresponding to the insulating layer in the thickness direction.

In the second embodiment of the reflective mask blank according to the present invention as shown in FIG. 2, the absorber film corresponds to the insulating layer. The present invention is however not limited to this embodiment.

In an alternative embodiment, for example, the insulating layer may be formed as another member different from the absorber film.

The sheet resistance of the layer adjacent to the insulating layer is preferably lower than 1.0×10³ Ω/sq., more preferably 7.5×10² Ω/sq. or lower, still more preferably 5.0×10² Ω/sq. or lower. In the embodiment shown in FIG. 2, the sheet resistance of the conductive layer 15 and the protective film 13 is preferably in the above preferable range.

In the second embodiment of the reflective mask blank according to the present invention, a bottom conductive film may be arranged on a bottom surface (second main surface) of the substrate opposite to the first main surface. The configuration of the bottom conductive film is as described above in the first embodiment of the mask blank.

### <Third Embodiment of Reflective Mask Blank>

The third embodiment of the reflective mask blank according to the present invention is shown in FIG. 3.

A reflective mask blank 10c shown in FIG. 3 has a substrate 11, a multilayer reflective film 12, a protective film 13 and an absorber film 14t arranged in this order. Further, a side conductor portion 16 is arranged on a side face of the absorber film 14t. The side conductor portion 16 is in contact with the side face of the absorber film 14t and a surface of the protective film 13. The absorber film 14t includes a first absorber film 14c and a second absorber film 14d arranged in this order from the substrate 11 side. The first absorber film 14c corresponds to the insulating layer having a sheet resistance of 1.0×10³ Ω/sq. or higher. The second absorber film 14d has a sheet resistance of lower than 1.0×10³ Ω/sq. Furthermore, the second absorber film 14d corresponds to the outermost layer (top layer) located on the outermost side of the reflective mask blank 10c opposite from the substate 11.

In the reflective mask blank 10c of FIG. 3, the first absorber film 14d as the insulating layer is arranged between the second absorber film 14d as the outermost layer and the protective film 13. In the reflective mask blank 10c, on the other hand, the side conductor portion 16 is arranged in contact with the side face of the second absorber film 14d and the surface of the protective film 13 so that the side conductor portion 16 ensures conductivity between the second absorber film 14d and the protective film 13. Thus, the reflective mask blank 10c achieves an internal electrical resistance of 100 kΩ or lower between the surface of the second absorber film 14d as the outermost layer opposite from the substrate 11 and the protective film 13 even though the first absorber film 14c as the insulating layer is arranged between the second absorber film 14d as the outermost layer and the protective film 13. The achievement of such an internal electrical resistance allows, even when charged particle beam processing is performed from the surface of the second absorber film 14d, electric charge in the second absorber film 14d as the outermost layer to be easily transferred to the protective film 13, thereby suppressing charging of the second absorber film 14d and consequently making it less likely that a processing error will occur due to bending of the charged particle beam.

The measurement method of the internal electrical resistance between the outermost layer and the protective film in the third embodiment of the reflective mask blank according to the present invention is the same as the measurement method of the internal electrical resistance in the first embodiment of the reflective mask blank.

Further, the preferable range of the internal electrical resistance in the third embodiment of the reflective mask blank according to the present invention is the same as the preferable range of the internal electrical resistance in the first embodiment of the reflective mask blank.

When compared, the reflective mask blank 10a of FIG. 1 and the reflective mask blank 10c of FIG. 3 are the same in configurations except that: the reflective mask blank 10c of FIG. 3 does not have a conductive layer; the absorber film has a predetermined two-layer structure; and the arrangement position of the side conductor portion is different. Thus, description of the same configurations will be omitted; and the following description will mainly be made only of the above different configurations.

In the third embodiment of the reflective mask blank according to the present invention, the absorber film has a two-layer structure of the first absorber film 14c and the second absorber film 14d.

As mentioned above, the first absorber film 14c is the layer having a sheet resistance of 1.0×10³ Ω/sq. or higher. In other hand, the first absorber film 14c not only functions as the absorber film but also corresponds to the insulating layer having a sheet resistance higher than or equal to a predetermined value.

The above sheet resistance can be measured in the same manner as the measurement method of the sheet resistance of the protective film.

As the material constituting the first absorber film 14c, for example, a material containing the above-mentioned second element and O may be mentioned. Specific examples of such a material include a Ta oxide, a Ta oxynitride, a Ta oxyboride, a Cr oxide, a Cr oxynitride and a Cr oxyboride.

In order to allow a smaller processing error in charged particle beam processing, the sheet resistance of the second absorber film 14d is preferably lower than 1.0×10³ Ω/sq., more preferably 7.5×10² Ω/sq. or lower, still more preferably 5.0×10² Ω/sq. or lower. The lower limit of the sheet resistance of the second absorber film 14d is not particularly limited. The sheet resistance of the second absorber film 14d is, for example, 1.0×10⁰ Ω/sq. or higher, and is preferably 1.0×10¹ Ω/sq. or higher.

The above sheet resistance can be measured in the same manner as the measurement method of the sheet resistance of the protective film.

As the material constituting the second absorber film 14d, for example, a material containing the above-mentioned first element may be mentioned. Specific examples of such a material include an elemental Ru metal, a Ru nitride, a Ru oxide, a Ru oxynitride, a Ru boride, an elemental Ir metal, an Ir nitride, an Ir oxide of Ir, an Ir oxynitride, an Ir boride, a Ta nitride and an elementary Pt metal.

In the third embodiment of the reflective mask blank according to the present invention, the side conductor portion is arranged on the side face of the absorber film. The side conductor portion is a member brought into contact with the side face of the absorber film and the surface of the protective film to ensure electrical conduction between the second absorber film as the outermost layer and the protective film. More specifically, in FIG. 3, the side conductor portion 16 are in contact with the second absorber film 14d and the protective film 13, which are respectively adjacent to both surfaces of the first absorber film 14c as the insulating layer.

The material constituting the side conductor portion preferably contains, for example, at least one element selected from the group consisting of Li, B, C, F, Na, Mg, Al, Si, K, Ca, Sn and transition metal elements.

Among others, the material constituting the side conductor portion is preferably the same as the material constituting the conductive layer in terms of productivity.

The method for forming the side conductor portion is not particularly limited. The side conductor portion can be obtained by, for example, forming the multilayer reflective layer, the protective film and the absorber film on the substrate, and then, sputtering the material constituting the side conductor portion.

In the case where the side conductor portion is formed of the same material as the second absorber film, the side conductor portion may be formed simultaneously with the formation of the second absorber film.

More specifically, for example, the multilayer reflective film and the protective film are first formed in this order on the substrate. Next, the first absorber film is formed by limiting the area of formation of the first absorber film such that an end of the first absorber film to be formed is positioned closer to the center of the substrate than an end of the protective film formed. After the formation of the first absorber film, the second absorber film is formed on the first absorber film, and simultaneously, the side conductor portion of the same material as the second absorber film layer is formed on the side face of the first absorber film.

The detailed production procedure will be described later.

In the third embodiment of the reflective mask blank according to the present invention as shown in FIG. 3, the absorber film has a two-layer structure. The present invention is however not limited to this embodiment.

In an alternative embodiment, the absorber film may have a structure of three or more layers, one of which corresponds to the above-mentioned insulating layer. For example, the absorber film may have a three-layer structure in which: the first absorber film, the second absorber film and the third absorber film are arranged in this order from the substrate side; and the second absorber film corresponds to the insulating layer. In this case, the third absorber film corresponds to the top layer.

The sheet resistance of the layer adjacent to the insulating layer is preferably lower than 1.0×10³ Ω/sq., more preferably 7.5×10² Ω/sq. or lower, still more preferably 5.0×10² Ω/sq. or lower. In the embodiment shown in FIG. 3, the sheet resistance of the second absorber film 14d and the protective film 13 is preferably in the above preferable range.

In the third embodiment of the reflective mask blank according to the present invention as shown in FIG. 3, the position of the end of the absorber film is closer to the center of the substrate than the position of the end of the protective film. The present invention is however not limited to this embodiment.

For example, the positions of the ends of the protective film and the absorber film may be substantially in agreement with each other; and the side conductor portion may be arranged on the side face of the absorber film. Further, the positions of the ends of the substrate, the multilayer reflective film, the protective film, the absorber film and the conductive layer may be substantially in agreement with one another; and the side conductor portion may be arranged on the entire side face of the reflective mask blank.

In the third embodiment of the reflective mask blank according to the present invention, a bottom conductive film may be arranged on a bottom surface (second main surface) of the substrate opposite to the first main surface. The configuration of the bottom conductive film is as described above in the first embodiment of the mask blank.

### <Fourth Embodiment of Reflective Mask Blank>

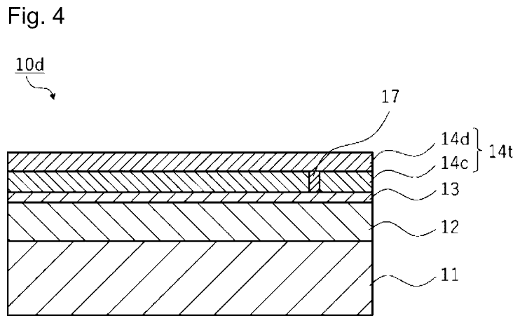

The fourth embodiment of the reflective mask blank according to the present invention is shown in FIG. 4.

A reflective mask blank 10d shown in FIG. 4 has a substrate 11, a multilayer reflective film 12, a protective film 13 and an absorber film 14t arranged in this order. The absorber film 14t includes a first absorber film 14c and a second absorber film 14d arranged in this order from the substrate 11 side. The first absorber film 14c corresponds to the insulating layer having a sheet resistance of 1.0×10³ Ω/sq. or higher. The second absorber film 14d has a sheet resistance of lower than 1.0×10³ Ω/sq. Further, the second absorber film 14d corresponds to the outermost layer (top layer) located on the outermost side of the reflective mask blank 10d opposite from the substrate 11. Furthermore, a through conductor portion 17 is arranged passing through the first absorber film 14c in the thickness direction. The through conductor portion 17 is in contact with the second absorber film 14d and the protective film 13. In the reflective mask blank 10d of FIG. 4, the first absorber film 14c as the insulating layer is arranged between the second absorber film 11d as the outermost layer and the protective film 13. In the reflective mask blank 10d, on the other hand, the through conductor portion 17 is arranged passing through the first absorber film 14c in the thickness direction so that the through conductor portion 17 ensures conductivity between the second absorber film 14d and the protective film 13. Thus, the reflective mask blank 10d achieves an internal electrical resistance of 100 kΩ or lower between the surface of the second absorber film 14d as the outermost layer opposite from the substrate 11 and the protective film 13 even when the first absorber film 14c as the insulating layer is arranged between the second absorber film 14d as the outermost layer and the protective film 13. The achievement of such an internal electrical resistance allows, when charged particle beam processing is performed from the surface of the second absorber film 14d, electric charge in the second absorber film 14d as the outermost layer to be easily transferred to the protective film 13, thereby suppressing charging of the second absorber film 14d and consequently making it less likely that a processing error will occur due to bending of the charged particle beam.

The measurement method of the internal electrical resistance between the outermost layer and the protective film in the fourth embodiment of the reflective mask blank according to the present invention is the same as the measurement method of the internal electrical resistance in the first embodiment of the reflective mask blank. Further, the preferable range of the internal electrical resistance in the fourth embodiment of the reflective mask blank according to the present invention is the same as the preferable range of the internal electrical resistance in the first embodiment of the reflective mask blank.

When compared, the reflective mask blank 10c of FIG. 3 and the reflective mask blank 10d of FIG. 4 are the same in configurations except that the reflective mask blank 10d of FIG. 4 does not have a side conductor portion but has a through conductor portion. Thus, description of the same configurations will be omitted; and the following description will mainly be made only of the through conductor portion.

### [Through Conductor Portion]

In the fourth embodiment of the reflective mask blank according to the present invention, the through conductor portion is arranged in the first absorber film as the insulating layer. The through conductor portion is a member brought into contact with the surface of the second absorber film and the surface of the protective film to ensure electrical conduction between the second absorber film as the outermost layer and the protective film. More specifically, in FIG. 4, the through conductor 17 is in contact with the protective film 13 and the second absorber film 14d, which are respectively adjacent to both surfaces of the first absorber film 14c as the insulating layer.

The material constituting the through conductor portion preferably contains, for example, at least one element selected from the group consisting of Li, B, C, F, Na, Mg, Al, Si, K, Ca, Sn and transition metal elements.

Among others, the material constituting the through conductor portion is preferably the same as the material constituting the conductive layer in terms of productivity.

Although the though conductor portion 17 is arranged at one location in the embodiment shown in FIG. 4, such conductor portions may be arranged at two or more locations.

Preferable examples of the shape of the through conductor portion and the maximum width of the cross section of the through conductor portion are the same as those of the through conductor portion in the second embodiment.

The method for forming the through conductor portion is not particularly limited. For example, there may be mentioned a method in which a through hole is formed in the insulating layer (in FIG. 4, the first absorber film) during or after the formation of the insulating layer, followed by forming the conductive layer. By the above-mentioned method, the through conductor portion is formed of the same material as that of the conductive layer.

As the method for forming the though conductor portion though the insulating layer in the thickness direction, there may also be mentioned a method in which, at the time of formation of the insulating layer, particles having a height larger than or equal to the thickness of the insulating layer to be formed are applied to the surface of the layer on which the insulating layer is to be formed. As the method for applying the particles, the same method as in the second embodiment may be mentioned.

In the fourth embodiment of the reflective mask blank according to the present invention as shown in FIG. 4, the absorber film has a two-layer structure. The present invention is however not limited to this embodiment.

In an alternative embodiment, the absorber film may have a structure of three or more layers, one of which corresponds to the above-mentioned insulating layer. For example, the absorber film may have a three-layer structure in which: the first absorber film, the second absorber film and the third absorber film are arranged in this order from the substrate side; and the second absorber film corresponds to the insulating layer. In such an embodiment, the through conductor portion is arranged passing through the second absorber film in the thickness direction. In this case, the third absorber film corresponds to the top layer.

In the fourth embodiment of the reflective mask blank according to the present invention as shown in FIG. 4, the first absorber film corresponds to the insulating layer. The present invention is however not limited to this embodiment.

In an alternative embodiment, for example, the insulating layer may be formed as another member different from the absorber layer.

The sheet resistance of the layer adjacent to the insulating layer is preferably lower than 1.0×10³ Ω/sq., more preferably 7.5×10² Ω/sq. or lower, still more preferably 5.0×10² Ω/sq. or lower. In the embodiment shown in FIG. 4, the sheet resistance of the second absorber film 14d and the protective film 13 is preferably in the above preferable range.

In the fourth embodiment of the reflective mask blank according to the present invention, a bottom conductive film may be arranged on a bottom surface (second main surface) of the substrate opposite to the first main surface. The configuration of the bottom conductive film is as described above in the first embodiment of the mask blank.

### <Reflective Mask Blank Production Method>

Hereinafter, first and second embodiments of a production method of a reflective mask blank according to the present invention will be described below.

### First Embodiment

The first embodiment of the reflective mask blank production method according to the present invention includes: providing a laminate which has a substrate, a multilayer reflective film for reflecting EUV light, a protective film and an absorber film having a single-layer structure or a multilayer structure in this order and in which an insulating layer having a sheet resistance of 1.0×10³ Ω/sq. or higher is arranged on a side closer to the absorber film than the protective film; forming, on the absorber film of the laminate, a conductive layer having a sheet resistance of lower than 1.0×10³ Ω/sq.; and forming a side conductor portion to cover at least a side face of the insulating layer and be in electrical conduction with the conductive layer.

The first embodiment of the reflective mask blank production method according to the present invention will be now described in detail with reference to FIG. 1. In the first embodiment, there can be produced e.g. a reflective mask blank 10a in which: a multilayer reflective film 12 for reflecting EUV light, a protective film 13, an absorber film 14 and a conductive layer 15 are arranged in this order on a substrate 11; and a side conductor portion 16 is arranged on side faces of the absorber film 14 and the conductive layer 15.

First, the substrate 11 is prepared, and the multilayer reflective film 12 is formed on the substrate 11. The multilayer reflective film can be formed by the above-mentioned method. Each of the layers constituting the multilayer reflective film can be formed with a desired thickness by a known film formation method such as a magnetron sputtering method, an ion beam sputtering method or the like.

The protective film 13 is next formed on the multilayer reflective film 12. The protective film 13 can be formed as mentioned above by a known film formation method such as a magnetron sputtering method, an ion beam sputtering method or the like.

Subsequently, the absorber film 14 is formed on the protective film 13. The absorber film 14 can be formed as mentioned above by a known film formation method such as a magnetron sputtering method, an ion beam sputtering method or the like. The absorber film 14 herein formed may preferably correspond to the above-mentioned insulating layer.

During the formation of the absorber film 14, the area of formation of the absorber film 14 may preferably be set narrower than the area of formation of the protective film 13. As the method for narrowing the area of formation of the absorber film 14, there may be mentioned a method in which, at the time of formation of the absorber film 14, a mask is applied to cover a portion of the protective film 13 and thereby limit the area of formation of the absorber film 14. The mask for covering a portion of the protective film is preferably an end mask that covers a certain area from the end of the protective film 13. The end mask is preferably of the type that covers an area of 0.05 to 5.0 mm, more preferably 0.1 to 1.0 mm, from the end of the protective film 13. The end mask may cover a part of the end portion of the protective film 13 or may cover the entire end portion of the protective film 13.

The conductive layer 15 is then formed on the absorber film 14. The sheet resistance of the conductive layer 15 herein formed is lower than 1.0×10³ Ω/sq. The sheet resistance can be measured by the above-mentioned method.

At the time of formation of the conductive layer 15, the side conductor portion 16 is also formed to cover at least the side face of the insulating layer (second absorber film) and be in electrical conduction with the conductive layer.

The formation of the conductive layer 15 and the formation of the side conductor portion 16 can be conducted simultaneously or separately. In terms of productivity, the simultaneous formation of the conductive layer and the side conductor portion is preferred.

For the simultaneous formation of the conductive layer 15 and the side conductor portion 16, there may be used e.g. a method in which the side conductor portion 16 is formed on the side face of the absorber film 14 by arranging at least a part of the target used for formation of the conductive layer 15 on a side of the end portion of the absorber film 14 opposite from the center of the substrate 11.

As another method, there may be mentioned a method in which: the absorber film 14 is formed on a narrower area than that of the protective film 13 with the use of the end mask; the conductive layer 15 is formed without the use of the end mask.

As another method, there may be mentioned a method in which: the absorber film 14 is formed on a narrower area than that of the protective film 13 with the use of the end mask; and the conductive layer 15 is formed with the use of a mask having an opening larger than that of the mask used for formation of the absorber film 14.

As another method, there may also be mentioned a method in which: the absorber film 14 is formed on a narrower area than that of the protective film 13 with the use of the end mask; and, with the end mask rotated by about 0.1 to 10 degrees, the conductive layer 15 is formed.

According to the above-mentioned methods, the same material as the conductive layer 15 is applied to not only the top surface of the absorber film 14 but also the side face of the absorber film 14 whereby the side face of the absorber film 14 is covered with the same material as the conductive layer 15.

By the first embodiment of the reflective mask blank production method according to the present invention, it is possible to produce a reflective mask blank small in processing error in charged particle beam processing.

Herein, preferable examples of the reflective mask blank produced and its respective components are the same as described above. Further, the reflective mask blank herein produced may be a reflective mask blank other than that shown in FIG. 1.

### Second Embodiment

The second embodiment of the reflective mask blank production method according to the present invention includes: providing a laminate which has a substrate, a multilayer reflective film for reflecting EUV light, a protective film and an absorber film having a single-layer structure or a multilayer structure in this order and in which an insulating layer having a sheet resistance of 1.0×10³ Ω/sq. or higher is arranged on a side closer to the absorber film than the protective film, wherein the providing includes forming, on the absorber film, a top layer having a sheet resistance of lower than 1.0×10³ Ω/sq. as a part of the absorber film; and forming a side conductor portion to cover at least a side face of the insulating layer and be in electrical conduction with the top layer.

The second embodiment of the reflective mask blank production method according to the present invention will be now described in detail with reference to FIG. 3. In the second embodiment, there can be produced e.g. a reflective mask blank 10c in which: a multilayer reflective film 12 for reflecting EUV light, a protective film 13 and an absorber film 14t are arranged in this order on a substrate 11; the absorber film 14t includes a first absorber film 14c on a side closer to the protective film 13 and a second absorber film 14d on a side away from the protective film 13; and a side conductor portion 16 is arranged on a side face of the absorber film 14. In this case, the first absorber film 14c corresponds to the insulating layer having a sheet resistance of 1.0×10³ Ω/sq. or higher; and the second absorber film 14d corresponds to the top layer. The second absorber film 14d has a sheet resistance of lower than 1.0×10³ Ω/sq.

First, the substrate 11 is prepared, and the multilayer reflective film 12 is formed on the substrate 11. The multilayer reflective film 12 can be formed by the above-mentioned method. Each of the layers constituting the multilayer reflective film 12 can be formed with a predetermined thickness by a known film formation method such as a magnetron sputtering method, an ion beam sputtering method or the like.

The protective film 13 is next formed on the multilayer reflective film 12. The protective film 13 can be formed as mentioned above by a known film formation method such as a magnetron sputtering method, an ion beam sputtering method or the like.

Subsequently, the first absorber film 14c is formed on the protective film 13. The first absorber film 14c can be formed as mentioned above by a known film formation method such as a magnetron sputtering method, an ion beam sputtering method or the like. The first absorber film 14 herein formed may preferably correspond to the above-mentioned insulating layer.

During the formation of the first absorber film 14c, the area of formation of the first absorber film 14c may preferably be set narrower than the area of formation of the protective film 13. Since the method for narrowing the area of formation of the first absorber film 14 and its preferable examples are the same as those in the first embodiment, description thereof will be omitted.

The second absorber film 14d is then formed on the first absorber film 14c. The sheet resistance of the second absorber film 14d herein formed is lower than 1.0×10³ Ω/sq. The sheet resistance can be measured by the above-mentioned method.

At the time of formation of the second absorber film 14d, the side conductor portion 16 is formed to cover at least the side face of the insulating layer (first absorber film 14c) and be in electrical conduction with the second absorber film 14d.

The formation of the second absorber film 14d and the formation of the side conductor portion 16 can be conducted simultaneously or separately. In terms of productivity, the simultaneous formation of the second absorber film and the side conductor portion is preferred.

The second absorber film 14d can be formed as mentioned above by a known film formation method such as a magnetron sputtering method, an ion beam sputtering method or the like.

For the simultaneous formation of the second absorber film 14d and the formation of the side conductor portion 16, there may be used e.g. a method in which the side conductor portion 16 is formed on the side face of the first absorber film 14c by arranging at least a part of the target used for formation of the second absorber film 14d on a side of the end portion of the first absorber film 14c opposite from the center of the substrate 11.

As another method, there may be mentioned a method in which: the first absorber film 14c is formed on a narrower area than that of the protective film 13 with the use of an end mask as described in the first embodiment; and the second absorber film 14d is formed without the use of an end mask.

As another method, there may be mentioned a method in which: the first absorber film 14c is formed on a narrower area than that of the protective film 13 with the use of an end mask as described in the first embodiment; and the second absorber film 14d is formed with the use of a mask having an opening larger than that of the mask used for formation of the first absorber film 14c.

As another method, there may also be mentioned a method in which: the first absorber film 14c is formed on a narrower area than that of the protective film 13 with the use of an end mask as described in the first embodiment; and, with the end mask rotated by about 0.1 to 10 degrees, the second absorber film 14d is formed.

According to the above-mentioned methods, the same material as the second absorber film 14d is applied to not only the top surface of the first absorber film 14c but also the side face of the first absorber film 14c whereby the side face of the first absorber film 14c is covered with the same material as the second absorber film 14d.

By the second embodiment of the reflective mask blank production method according to the present invention, it is possible to produce a reflective mask blank small in processing error in charged particle beam processing.

Herein, preferable examples of the reflective mask blank produced and its respective components are the same as described above. Further, the reflective mask blank herein produced may be a reflective mask blank other than that shown in FIG. 3. For example, the absorber film may have a structure of three or more layers, any one of which corresponds to the above-mentioned insulating layer. The absorber film may have e.g. a three-layer structure in which: the first absorber film, the second absorber film and the third absorber film are arranged in this order from the substrate side; and the second absorber film corresponds to the insulating layer. In this case, the third absorber film corresponds to the top layer and has a sheet resistance of lower than 1.0×10³ Ω/sq.

### <Reflective Mask Production Method and Reflective Mask>

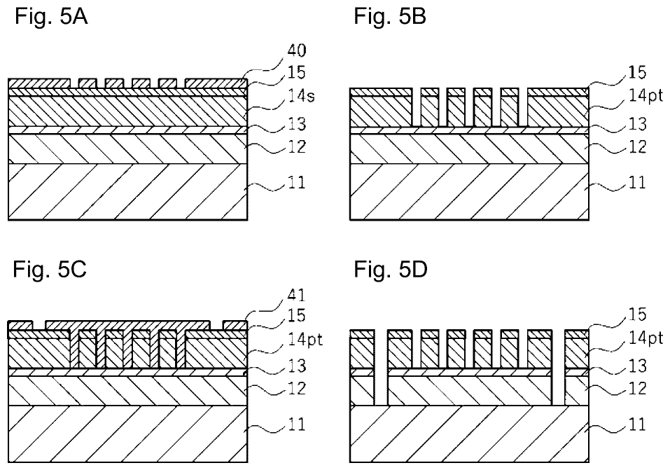

A reflective mask is obtained by pattering the absorber film of the reflective mask blank according to the present invention. An example of a production method of such a reflective mask will be described below with reference to FIGS. 5A-5D. Although the following description will be given of a method for production of a reflective mask using the reflective mask blank 10b of the second embodiment shown in FIG. 2, it should be understood that a reflective mask can be obtained by a similar method using the reflective mask blank of any other embodiment.

FIG. 5A illustrates a state of a resist pattern 40 formed on the reflective mask blank in which the substrate 11, the multilayer reflective film 12, the protective film 13, the absorber film 14s and the conductive layer 15 are arranged in this order. As the method for forming the resist pattern 14, a known method can be used. For example, the resist pattern 40 can be formed by applying a resist to the conductive layer 15 of the reflective mask blank and subjecting the resist to exposure and development. The resist pattern 40 is in match with a pattern to be formed on a wafer using the reflective mask.

After that, the absorber film 14s and the conductive layer 15 are patterned by etching using the resist pattern 40 of FIG. 5A as a mask, and then, the resist pattern 40 is removed to obtain a laminate having an absorber film pattern 14pt as shown in FIG. 5B.

In the case where the conductive layer 15 corresponds to a hard mask film, a portion of the conductive layer 15 in an opening of the resist pattern 40 may be removed by etching before the etching of the absorber film 14s; and then, the absorber film 14s may be patterned by etching.

Subsequently, a resist pattern 41 is formed on the laminate of FIG. 5B in match with a frame of the exposure region as shown in FIG. 5C. The laminate is then subjected to dry etching using the resist pattern 41 of FIG. 5C as a mask. The dry etching is performed until reaching the substrate 11. After the dry etching, the resist pattern 41 is removed whereby the reflective mask is obtained as shown in FIG. 5D.

As the dry etching for formation of the absorber film pattern 14pt, dry etching using CI-based gas and dry etching using F-based gas may be mentioned.

In the case where the conductive layer 15 corresponds to a hard mask film, the etching of the conductive layer 15 via the opening of the resist pattern 40 can be wet etching using a chemical solution or can be dry etching. For the etching of the conductive layer 15, it may be preferable to select a method capable of etching the conductive layer 15 without etching the absorber film 14s.

The resist pattern 40 or 41 can be removed by a known method such as treatment with a cleaning liquid. Examples of the cleaning liquid include sulfuric acid-hydrogen peroxide mixture (SPM), sulfuric acid, ammonia, ammonia-hydrogen peroxide mixture (APM), OH radical cleaning water, ozone water, and the like.

The reflective mask obtained by pattering the absorber film of the reflective mask blank according to the present invention is suitable applicable as a reflective mask for use in EUV light exposure.

### EXAMPLES

Now, the present invention will be described in further detail with reference to the following Examples.

The materials, amounts used, ratios, processing operations, processing procedures in the following Examples can be changed as appropriate without departing from the scope of the present invention. It should thus be understood that the scope of the present invention is by no means restricted to the following Examples.

Herein, the following Ex. 1 to 5 correspond to Examples; and the following Ex. 6 and 7 correspond to Comparative Examples.

### <Production of Reflective Mask Blanks>

A reflective mask blank of Ex. 1 was produced by the following procedure.

As a substrate, used was a SiO₂—TiO₂ glass substrate (outer size: 152 mm square, thickness: about 6.3 mm). This glass substrate had a thermal expansion coefficient of 0.2×10⁻⁷/° C., a Young's modulus of 67 GPa, a Poisson's ratio of 0.17, and a specific stiffness of 3.07×10⁷ m²/s². The glass plate was used with a main surface of the glass substrate polished to a surface roughness (root mean square height Sq) of 0.15 nm or less and a flatness of 100 nm or less.

On a bottom surface of the glass substrate (opposite to the polished surface), a CrN layer having a thickness of about 100 nm was formed by magnetron sputtering as a bottom conductive film for electrostatic chucking. The sheet resistance of the CrN layer was about 100 Ω/sq.

Next, the glass substrate was fixed in a film forming chamber by an electrostatic adhesion method using an electrostatic chuck. In this state, a multilayer reflective film was formed on the first main surface (polished surface) of the glass substrate.

For formation of the multilayer reflective film, ion beam sputtering was used. Mo layers having a thickness of 2.3 nm and Si layers having a thickness of 4.5 nm were alternately formed forty times by ion beam sputtering whereby the Mo/Si multilayer reflective film was obtained.

The ion beam sputtering for formation of the Mo layers was performed using a Mo target in an Ar gas atmosphere (gas pressure: 0.02 Pa). The voltage applied was 700 V, and the sputtering rate was 3.84 nm/min.

On the other hand, the ion beam sputtering for formation of the Si layers was performed using a boron-doped Si target in an Ar gas atmosphere (gas pressure: 0.02 Pa). The voltage applied was 700 V, and the sputtering rate was 4.62 nm/min.

The total thickness (target value) of the multilayer reflective film was (2.3 nm+4.5 nm)×40=272 nm. The top layer of the multilayer reflective film was the Si layer.

Next, a protective film was formed by ion beam sputtering on the multilayer reflective film.

The protective film had a two-layer structure including a Ru layer and a Rh layer in this order from the substrate side.

The ion beam sputtering for formation of the Ru layer was performed using a Ru target in an Ar gas atmosphere (gas pressure: 0.02 Pa). The voltage applied was 700 V, and the sputtering rate was 3.12 nm/min. The thickness of the Ru layer was 1.0 nm.

The ion beam sputtering for formation of the Rh layer was performed using a Rh target in an Ar gas atmosphere (gas pressure: 0.027 Pa). The voltage applied was 600 V, and the sputtering rate was 4.62 nm/min. The thickness of the Rh layer was 1.5 nm.

Subsequently, an absorber film was formed on the protective film by magnetron sputtering.

The absorber film had a three-layer structure including a RuN layer, a TaN layer and TaON layer in this order from the substrate side. The absorber film was formed on an area of 148 mm square by applying a mask to a part of the protective film.

For formation of the Ru layer, the magnetron sputtering was performed using a Ru target in a mixed gas atmosphere of Ar gas and N₂ gas (Ar gas: 80 vol %, N₂ gas: 20 vol %) (gas pressure: 0.2 Pa). The voltage applied was 700 V, and the sputtering rate was 3.0 nm/min. The thickness of the RuN layer was 29 nm.

For formation of the TaN layer, the magnetron sputtering was performed using a Ta target in a mixed gas atmosphere of Ar gas and N₂ gas (Ar gas: 95 vol %, N₂ gas: 5 vol %). The sputtering rate was 1.74 nm/min. The thickness of the TaN layer was 8 nm.

For formation of the TaON layer, the magnetron sputtering was performed using a Ta target in a mixed gas atmosphere of Ar gas, N₂ gas and O₂ gas (Ar gas: 60 vol %, N₂ gas: 30 vol %, O₂ gas: 10 vol %). The sputtering rate was 0.6 nm/min. The thickness of the TaON layer was 14 nm.

Then, a conductive layer was formed by ion beam sputtering on the absorber film. This conductive layer corresponds to a hard mask film.

The conductive film formed was a Ru layer. Herein, the conductive layer was formed on an area of 149 mm square by applying a mask to a part of the absorber film. For formation of the Ru layer, the ion beam sputtering was performed using a Ru target in an Ar gas atmosphere (gas pressure: 0.2 Pa). The voltage applied was 700 V, and the sputtering rate was 3.0 nm/min. The thickness of the Ru layer was 10 nm. During the above conductive layer formation, a side conductor portion was also formed to cover a side face of the absorber film and a side face of the conductive layer and be in contact with a surface of the protective layer as shown in FIG. 1.

By the above procedure, the reflective mask blank of Ex. 1 was obtained.

The sheet resistance of the conductive layers of the reflective mask blanks of Ex. 1 and the after-mentioned reflective mask blanks of Ex. 2 to 7 as measured by the above-mentioned method is shown in Table below.

A reflective mask blank of Ex. 2 was produced in the same manner as the reflective mask blank of Ex. 1, except that a RuN layer was formed as the conductive layer.

The sputtering conditions for formation of the RuN layer were the same as those for formation of the above-mentioned RuN layer. The thickness of the RuN layer was 10 nm.

A reflective mask blank of Ex. 3 was produced in the same manner as the reflective mask blank of Ex. 1, except that a CrN layer was formed as the conductive layer.

For formation of the CrN, ion beam sputtering was performed using a Cr target in a mixed gas atmosphere of Ar gas and N₂ gas (Ar gas: 85 vol %, N₂ gas: 15 vol %) (gas pressure: 0.2 Pa). The sputtering rate was 1.6 nm/min. The thickness of the Cr layer was 10 nm.

A reflective mask blank of Ex. 4 was produced in the same manner as the reflective mask blank of Ex. 1, except that a TaN layer was formed as the conductive layer.

The sputtering conditions for formation of the TaN layer was the same as those for formation of the above-mentioned TaN layer. The thickness of the TaN layer was 10 nm.

The TaN layer herein formed as the conductive layer corresponds to an absorber film.

A reflective mask blank of Ex. 5 was produced by the following procedure.

First, a multilayer reflective film, a protective film and an absorber film were formed in the same manner as in the reflective mask blank of Ex. 2. In this example, however, the absorber film was formed on the entire surface of the protective film without using a mask.

After the formation of the absorber film, a hole of 10 μm square was formed in the absorber film such that the center position of the hole was 7.1 mm away from one corner of the substrate in a direction toward the center of the substrate. This hole was formed such that the RuN layer of the absorber film was exposed through the hole. For the formation of the hole, the after-mentioned focused ion beam processing machine was used.

Holes of 10 μm square were further formed, in the same manner as above, in the absorber film at positions 7.1 mm away from the other three corners of the substrate in directions toward the center of the substrate.

After the formation of the holes, a conductive layer was formed in the same manner as in the reflective mask blank of Ex. 2. With this, the reflective mask blank of Ex. 5 was obtained.

During the above conductive layer formation, through hole conductors were also formed in contact with a surface of the conductive layer and a surface of the protective film.

A reflective mask blank of Ex. 6 was produced in the same manner as the reflective mask blank of Ex. 1, except that no conductive layer was formed. In the reflective mask blank of Ex. 6, no side conductor portion was formed.

A reflective mask blank of Ex. 7 was produced as follows. A multilayer reflective film was first formed on a substrate in the same manner as in the reflective mask blank of Ex. 1.

Next, a protective film was formed on the multilayer reflective film by high frequency sputtering.

The protective film formed was a SiO layer.

For formation of the SiO layer, the high frequency sputtering was performed using a SiO₂ target in an Ar gas atmosphere. The thickness of the SiO layer was 2.6 nm.

Subsequently, an absorber film was formed on the protective film by magnetron sputtering.

The absorber film had a two-layer structure including a RuCrON layer and a RuCrO layer in this order from the substrate side.

For formation of the RuCrON layer, the magnetron sputtering was performed using a Ru target and a Cr target in a mixed gas atmosphere of Ar gas and N₂ gas (Ar gas: 70 vol %, N₂ gas: 20 vol %, O₂ gas: 10 vol %). The thickness of the RuCrON layer was 33.5 nm.

For formation of the RuCrO layer, the magnetron sputtering was performed using a Ru target and a Cr target in a mixed gas atmosphere of Ar gas and O₂ gas (Ar gas: 50 vol %, O₂ gas: 50 vol %). The thickness of the RuCrO layer was 8.5 nm.

Then, a hard mask film was formed on the absorber film by magnetron sputtering.

The hard mask film formed was a SiN layer.

For formation of the SiN layer, the magnetron sputtering was performed using a Si target in a N₂ gas atmosphere. The thickness of the SiN layer was 20 nm.

By the above procedure, the reflective mask blank of Ex. 7 was obtained.

### <Measurement and Evaluation>

### (Measurement of Internal Electrical Resistance)

An electrical resistance between the protective layer and the outermost layer of the reflective mask blank of each Ex. was measured with a Manual Prober (model number: HMP-400, manufactured by HiSOL Inc.). The measurement conditions were as mentioned above.

Herein, the preparation of a sample for internal electrical resistance measurement, that is, the exposure of the protective film was conducted by etching through contact of a treatment solution with a region where the protective film was to be exposed. The treatment solution used was a solution containing 45 mass % of potassium hydroxide and 1 mass % sodium periodate to the total mass of the treatment solution. For the exposure of the protective film, the treatment solution at 80° C. was brought into contact with the region where the protective film was to be exposed for 30 minutes. After the contact treatment, the mask blank was rinsed with pure water and dried. With this, the sample for internal electrical resistance measurement was obtained.

In the contact treatment with the treatment solution, the Ru layer was not dissolved and thus was exposed. Regarding the reflective mask blank of Ex. 6, the sample for internal electrical resistance measurement was obtained by performing contact treatment with a 85 mass % phosphoric acid solution at 160° C. for 30 minutes and then performing contact treatment with a solution at 25° C. containing 9 mass % of diammonium cerium(IV) nitrate and 6 mass % of perchloric acid for 30 minutes.

Regarding the reflective mask blanks of Ex. 1, 2 and 6, also prepared were samples for internal electrical resistance measurement in each of which the protective film had an exposed region defined by, after the formation of the protective film, forming the absorption film etc. with a mask applied to a region where the protective film was to be exposed. In comparison of the internal electrical resistance of the sample obtained by the above-mentioned film formation using the mask and the internal electrical resistance of the sample obtained by the etching treatment, there was seen no significant difference between these electrical resistance values.

### (Evaluation of Processing Error)

The processing error of the reflective mask blank of each Ex. was evaluated by the following procedure.

Using a focused ion beam processing machine (model number: SMI3050R, manufactured by Hitachi Hi-Tech Corporation), the reflective mask blank was processed with a charged particle beam so as to form an evaluation shape. As the ion species for emission of the ion beam, Ga was used. The acceleration voltage was set to 30 kV. The design shape for the evaluation shape was a rectangular parallelepiped shape of 1 μm length, 10 μm width and 0.1 μm depth.

The processing conditions of the focused ion beam processing machine were set such that the evaluation shape was accurately defined in the sample in which up to the Ru layer of the protective film had been formed in the production of the reflective mask blank of Ex. 1.

An observation sample was also prepared by, after the formation of the processed region by performing evaluation shape forming processing on the reflective mask blank, applying a Pt coating as an anti-static coating for a scanning electron microscope. The shape of the processed region in the observation sample was observed with a field emission scanning electron microscope (S-4800, manufactured by Hitachi Hi-Tech Corporation) from a direction perpendicular to the first main surface of the substrate of the observation sample.

The processing error was evaluated by comparison between the design shape for the evaluation shape and the shape of the processed region. The processing error value E (%) was determined by the following formula where the area of a portion of the processed region protruding from the design shape was assumed as S_{A} (μm²); the area of a portion of the processed region missing from the design shape was assumed as Ss (μm²); and the area of the design shape was assumed as S (μm²).

$$E = ( {S}_{A} + {S}_{S} ) / S$$

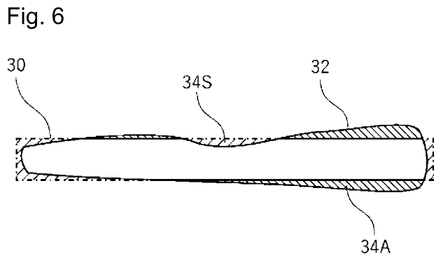

The portions of the processed region protruding from and missing from the design shape will be now explained with reference to FIG. 6. FIG. 6 is a schematic view illustrating an observation example in processing error evaluation of each Example. In FIG. 6, a region indicated by a dashed line is an imaginary region representing a design shape 30; and a region indicated by a solid line is a processed region 32 formed by processing. In FIG. 6, a protruding portion 34A is a portion outside the design shape 30 and inside the processed region 32; and a missing portion 34S is a portion inside the design shape 30 and outside the processed region 32. In the above formula, the protruding area S_{A} is the total area of the protruding portion 34A; and the missing area Ss is the total area of the missing portion 34S.

The processing error was rated based on the above-obtained processing error value E (%) according to the following criteria. For practical use, the rating of A or B is preferred.
A: The value E was less than 1%.
B: The value E was 1% or more and less than 5%.
C: The value E was 5% or more.

### <Results>

The layer structure, the sheet resistance, the internal electrical resistance and the processing error evaluation result of each Ex. are shown in Table 1.

Herein, the sheet resistance of each layer was measured by the above-mentioned method using the sample formed up until that layer.

In the column of “Insulating Layer Sheet Resistance” in Table 1, the kind and sheet resistance of the layer corresponding to the insulating layer are shown. In the case where there were two or more layers corresponding to the insulating layer, any of those layers having the highest sheet resistance is shown as the insulating layer.

In the columns of “Outermost Layer Sheet Resistance” and “Insulating Layer Sheet Resistance” in Table 1, the expression “>40 M” means that the sheet resistance was 40 MΩ/sq. or higher. Further, “k” in the expression “50 k” means the SI prefix “kilo”; and the expression “50 k” means that the sheet resistance was 50 kΩ/sq.

TABLE 1

| TABLE 1 | | Ex. 1 | Ex. 2 | Ex. 3 | Ex. 4 | Ex. 5 | Ex. 6 | Ex. 7 |
|---|---|---|---|---|---|---|---|---|
| Layer Structure | Hard Mask Film | Ru | RuN | CrN | — | RuN | — | SiN |
| | Absorber Film | — | — | — | TaN | — | — | — |
| | | TaON | TaON | TaON | TaON | TaON | TaON | — |
| | | TaN | TaN | TaN | TaN | TaN | TaN | RuCrO |
| | | RuN | RuN | RuN | RuN | RuN | RuN | RuCrON |
| | Protective Film | Rh | Rh | Rh | Rh | Rh | Rh | — |
| | | Ru | Ru | Ru | Ru | Ru | Ru | SiO |
| | Multilayer Reflective Film | Si/Mo | Si/Mo | Si/Mo | Si/Mo | Si/Mo | Si/Mo | Si/Mo |
| Properties | Outermost Layer Sheet | 87 | 91 | 249 | 50k | 102 | >40M | >40M |
| | Resistance | | | | | | | |
| | Insulating Layer Sheet | TaON | TaON | TaON | TaON | TaON | TaON | SiN |
| | Resistance | >40M | >40M | >40M | >40M | >40M | >40M | >40M |
| | Internal Electrical | 84 | 87 | 250 | 871 | 55 | >40M | >40M |
| | Resistance | | | | | | | |
| Rating | Processing Error | A | A | A | B | A | C | C |

By the results of Ex. 1 to 5 in Table 1, it has been shown that the reflective mask blank according to the present invention is small in processing error in charged particle beam processing. On the other hand, as is seen from the results of Ex. 6 and 7, the processing error was large in charged particle beam processing when the internal electrical resistance was higher than or equal to a predetermined value.

### REFERENCE SYMBOLS

10a to 10d: Reflective mask blank
11: Substrate
12: Multilayer reflective film
13: Protective film
14, 14s, 14t: Absorber film
14a, 14c: First absorber film
14b, 14d: Second absorber film
14pt: Absorber film pattern
15: Conductive layer
16: Side conductor portion
17: Through conductor portion
30: Design shape
32: Processing area
34S: Missing portion
34A: Protruding portion
40, 41: Resist pattern

What is claimed is:

1. A reflective mask blank, comprising in the following order:
a substrate;
a multilayer reflective film for reflecting EUV light;
a protective film; and
an absorber film having a single-layer structure or a multilayer structure, wherein:
any layer between the outermost layer located on the outermost side of the reflective mask blank opposite from the substrate and the protective film is an insulating layer having a sheet resistance of 1.0×10³ Ω/sq. or higher, and
wherein an interlayer electrical resistance between a surface of the outermost layer opposite from the substrate and the protective film is 100 kΩ or lower.

2. The reflective mask blank according to claim 1, comprising a conductive layer arranged on the absorber film and having a sheet resistance of lower than 1.0×10³ Ω/sq., wherein the conductive layer is the outermost layer.

3. The reflective mask blank according to claim 2, wherein the absorber film comprises the any layer formed as the insulating layer.

4. The reflective mask blank according to claim 1, wherein:
the absorber film has a multilayer structure,
a top layer of the absorber film located farthest away from the substrate has a sheet resistance of lower than 1.0×10³ Ω/sq., and the top layer is the outermost layer.

5. The reflective mask blank according to claim 4, wherein the absorber film comprises the any layer formed as the insulating layer.

6. The reflective mask blank according to claim 1, wherein the protective film has a sheet resistance of lower than 1.0×10³ Ω/sq.

7. The reflective mask blank according to claim 1, wherein the insulating layer has a thickness of 30 nm or smaller.

8. The reflective mask blank according to claim 1, comprising a conductor portion arranged between the outermost layer and the protective film to provide electrical conduction between layers respectively adjacent to both surfaces of the insulating layer.

9. The reflective mask blank according to claim 8, wherein:
the conductor portion comprises a side conductor portion arranged on at least a side face of the insulating layer; and
the side conductor portion is in contact with at least the layers respectively adjacent to the both surfaces of the insulating layer.

10. The reflective mask blank according to claim 9, wherein the side conductor portion is arranged on side faces of all of the layers between the outermost layer and the protective film.

11. The reflective mask blank according to claim 8, wherein the conductor portion comprises a through conductor portion arranged in and passing through the insulating layer in a thickness direction thereof.

12. The reflective mask blank according to claim 8, wherein the conductor portion contains at least one element selected from the group consisting of lithium, boron, carbon, fluorine, sodium, magnesium, aluminum, silicon, potassium, calcium, tin and transition metal elements.

13. The reflective mask blank according to claim 1, wherein the outermost layer contains at least one element selected from the group consisting of titanium, chromium, cobalt, nickel, copper, zirconium, niobium, molybdenum, ruthenium, rhodium, palladium, indium, tin, hafnium, tantalum, tungsten, rhenium, osmium, iridium and platinum.

14. The reflective mask blank according to claim 1, wherein the outermost layer contains at least one element selected from the group consisting of nitrogen, oxygen, boron, silicon and carbon.

15. A reflective mask comprising an absorber film pattern formed by patterning of the absorber film of the reflective mask blank as defined in claim 1.

16. A method for producing a reflective mask, comprising patterning the absorber film of the reflective mask as defined in claim 1.

17. A method for producing a reflective mask blank, comprising: providing a laminate which comprises, in the following order, a substrate, a multilayer reflective film for reflecting EUV light, a protective film and an absorber film having a single-layer structure or a multilayer structure and in which an insulating layer having a sheet resistance of 1.0×10³ Ω/sq. or higher is arranged on a side closer to the absorber film than the protective film; forming, on the absorber layer, a conductive layer having a sheet resistance of lower than 1.0×10³ Ω/sq.; and forming a side conductor portion to cover at least a side face of the insulating layer and be in electrical conduction with the conductive layer.

18. A method for producing a reflective mask blank, comprising: providing a laminate which comprises, in the following order, a substrate, a multilayer reflective film for reflecting EUV light, a protective film and an absorber film having a single-layer structure or a multilayer structure and in which an insulating layer having a sheet resistance of 1.0×10³ Ω/sq. or higher is arranged on a side closer to the absorber film than the protective film, wherein the providing includes forming, on the absorber film, a top layer having a sheet resistance of lower than 1.0×10³ Ω/sq. as a part of the absorber film; and forming a side conductor to cover at least a side face of the insulating layer and be in electrical conduction with the top layer.
